(19) United States
(12) Patent Application Publication
(10) Pub. No.: US 2012/0167968 A1
(43) Pub. Date: Jul. 5, 2012

(54) METHOD FOR PRODUCING SOLAR CELLS HAVING SELECTIVE EMITTER

(76) Inventors: Jan Lossen, Erfurt (DE); Mathias Weiss, Jena (DE); Karsten Meyer, Erfurt (DE); Tobias Wuetherich, Erfurt (DE)

(21) Appl. No.: 13/259,835

(22) PCT Filed: Mar. 26, 2010
(86) PCT No.: PCT/EP10/53985

§ 371 Date: Mar. 19, 2012

(30) Foreign Application Priority Data
Mar. 27, 2009 (DE) 10 2009 015 367.5
Sep. 15, 2009 (DE) 10 2009 041 546.7

(51) Int. Cl. H01L 31/0352; H01L 31/18

(52) U.S. Cl. 136/255; 438/73; 257/E31.001

(57) ABSTRACT

A method is described for manufacturing solar cells having a selective emitter. Wafers free of saw damage are initially provided. A doping source is then applied over the entire surface of the wafer and the dopant is initially lightly diffused into the wafer until a first layer resistance area is obtained. The applied doping source is subsequently structured, only those areas which essentially correspond to the sections on the wafer to be subsequently contacted remaining as a result of the structuring. An additional second diffusion from the remaining areas of the doping source into the wafer volume is conducted until a second layer resistance area for the selective emitter is obtained and simultaneous redistribution of the dopant introduced during the first diffusion with the goal of reducing the doping concentration in the area near the surface which is no longer covered by the doping source, provided that the layer resistance values of the first layer resistance area are greater than those of the second layer resistance area.

### FIELD OF THE INVENTION

The present invention relates to a method for manufacturing solar cells having a selective emitter.

### BACKGROUND INFORMATION

Solar cells are currently manufactured industrially using the so-called firing-through SiNx process. A homogeneous emitter having a layer or surface resistance in the range of 40 Ω/□ to 80 Ω/□ is produced on the cell front side by diffusing phosphorous. An additional layer of silicon nitride used for passivation and reflection reduction is applied on this layer. A contact grid of silver paste is subsequently applied. The aforementioned paste is baked in a sintering step. Special components in the silver paste allow the formation of an electrical contact between the contact grid and the actual emitter. A disadvantage of this type of contact formation is the necessity of very high doping of the emitter to obtain a sufficiently low contact resistance. This in turn results in high losses in the areas between the formed contact fingers due to recombination of the charge carriers.

So-called selective emitters for solar cells were proposed to overcome this disadvantage. In the case of these cells, only the contact area is highly doped, the rest of the wafer surface having low doping.

An option for producing selective emitter structures is to apply a diffusion mask and to open it at the desired locations, e.g., by printing an etching paste onto certain areas or by laser ablation, to then perform a significant diffusion into the volume of the wafer. The mask must subsequently be removed and a further diffusion is to be implemented over the whole surface with the goal of forming low-doping sections.

In another variant of the related art, a weak diffusion is initially performed. According to AU 570 309, a weak diffusion may be initially performed over the entire surface of the wafers. A very dense silicon nitride layer which serves as a mask and later as an anti-reflection layer is subsequently applied with the aid of an LPCVD step. Trenches are cut in the substrate with the aid of a laser. Strong doping into these trenches is then performed. The trenches are then metallized by nickel-copper-tin plating.

A method for producing a silicon solar cell having a selective emitter is discussed in DE 10 2007 035 068 A1. A planar emitter is created on a surface of the substrate in a first step of this method. An etching barrier is then applied on first sub-areas of the emitter surface. This step is followed by etching of the emitter surface in second sub-areas not covered by the etching barrier. After removal of the etching barrier, metal contacts are created in the first sub-areas. In DE 10 2007 035 068 A1 it is discussed as advantageous that a porous silicon layer that is subsequently oxidizable is created during the process, in particular during etching of the emitter surface in the second sub-areas. This oxidized porous silicon layer may subsequently be etched away together with any present phosphorus glass. By using known screen printing and etching technologies, this method should be compatible with current industrial production facilities.

If the discussions in DE 10 2007 035 068 A1 are summarized, the main idea is to initially produce an emitter on at least one surface of a solar cell substrate having a homogeneous doping concentration that is high enough to be suitable for contacting in the subsequent screen printing process. First sub-areas of the already present emitter surface are protected by an etching barrier directly after, which may be prior to the deposition of an anti-reflective layer or passivation layer. The unprotected areas are subjected to the etching step so that the thickness of the emitter is reduced in the mentioned areas with the result that an emitter having an increased layer resistance is created in these second sub-areas.

In the method for producing a silicon solar cell having a back-etched emitter according to DE 10 2007 062 750 A1, a planar emitter is produced on a surface of a solar cell substrate in a first step. A layer of porous silicon is subsequently created and is then subjected to targeted back-etching. For the step of producing a planar emitter, any method may be used according to DE 10 2007 062 750 A1. For example, it is possible to form the planar emitter with the aid of a POCl₃ gas phase diffusion by diffusing phosphorous from a hot gas phase into the surface of the substrate. The parameters during production of the planar emitter should be selected in such a way that an emitter layer resistance of less than 60 Ω/□ may materialize. An etching barrier is applied on the created first sub-areas of the front side surface of the substrate. The etching barrier protects the underlying first sub-areas of the emitter surface from the etching medium. The emitter surface is etched in the etching step in the second sub-areas until a desired high layer resistance of for example more than 60 Ω/□ materializes in the remaining emitter layer. During the etching process, the layer resistance is checked by a measurement so that the etching process may be aborted in a targeted manner. In one refinement of the method according to DE 10 2007 062 750 A1, an additional step regarding the creation of the mentioned porous silicon layer is performed. This process step is performed after deposition of the etching barrier on the second sub-areas of the emitter surface of the substrate not covered by the etching barrier. Instead of etching the emitter surface over the surface of the areas not protected by the etching barrier, an etching process resulting in the formation of an at least partially porous silicon layer may also be used. This porous silicon layer is oxidized in a later method step.

The photovoltaic cell having two or more selectively diffused areas according to DE 697 31 485 T2 assumes that the selective areas are created with the aid of a single diffusion step.

To be able to create different selectively diffused areas on the semiconductor substrate having different doping material levels, screen printing of solid material-based doping pastes is assumed to subsequently form the diffusion areas using a first high-temperature heat treatment step. A second high-temperature heat treatment step is performed after the screen printing of a metal paste for the contact fingers.

Reference is made to R. E. Schlosser et al., “Manufacturing of Transparent Selective Emitter and Boron Back-Surface Solar Cells Using Screen Printing Technique,” 21st European Photovoltaic Solar Energy Conference, Sep. 4-8, 2006, Dresden as further related art.

The above-described approaches of the related art have different disadvantages.

Homogeneous emitters as typically used previously in industrial production have relatively poor optical and electronic properties. To achieve a sufficiently low contact resistance, significantly stronger doping than is necessary for sufficient electrical function must be performed. The excessive doping is noticeable as an excessively high emitter saturation current having a negative effect on the open terminal voltage and the fill factor. Due to the short charge carrier service life in the highly doped emitter, charge carriers produced there cannot be separated, resulting in a reduction of the short-circuit current and finally in reduced efficiency of the solar cell.

The proposed methods for manufacturing selective emitters avoid the abovementioned disadvantages at least selectively, but are not suitable for cost-effective industrial implementation for various reasons.

The described method including masking and two diffusion steps includes numerous process steps and is therefore cost-intensive.

The use of a mask for opening the area to be subsequently contacted is not economical since more than 80% of the surface needs to be covered with an etching mask, e.g., an etching paint, which also results in high costs.

Opening with an etching paste applied during screen printing or by laser ablation entails, on the one hand, increased safety precautions when using aggressive paste materials and, on the other hand, a significant damage to the surface during laser ablation treatment.

Although the approach according to DE 10 2007 035 068 A1 reduces the need for cover paint, it is, however, disadvantageous that the layer resistance in the low-doped area is produced by back-etching. However, the etching processes described there are not self-limiting. Inhomogeneities in the etching bath, such as temperature or concentration of the etching medium or decomposition products, therefore result in an inhomogeneity in the layer resistance having a disadvantageous effect on the cell efficiency. The necessary etching solutions are extremely aggressive, making it difficult to select a suitable masking paint. Moreover, the emitter profile produced after back-etching still has a very high surface concentration of the dopant with the consequence of an undesirable high emitter saturation current.

### SUMMARY OF THE INVENTION

For the above-mentioned reasons, it is therefore an object of the exemplary embodiments and/or exemplary methods of the present invention to provide a refined method for manufacturing solar cells having a selective emitter which as a result advances the creation of solar cells which have a higher energy conversion efficiency, and whereby the amount of required masking materials is reduced.

An object of the exemplary embodiments and/or exemplary methods of the present invention is achieved by a method according to the description herein, the further embodiments and methods representing at least functional embodiments and further refinements are also described herein.

### BRIEF DESCRIPTION OF THE DRAWINGS

FIG. 1a shows one aspect of the solar cell structure and method as provided for in the context of the described embodiments and/or methods of the present invention.

FIG. 1b shows another aspect of the solar cell structure and method as provided for in the context of the described embodiments and/or methods of the present invention.

FIG. 1c shows another aspect of the solar cell structure and method as provided for in the context of the described embodiments and/or methods of the present invention.

FIG. 1d shows another aspect of the solar cell structure and method as provided for in the context of the described embodiments and/or methods of the present invention.

FIG. 1e shows another aspect of the solar cell structure and method as provided for in the context of the described embodiments and/or methods of the present invention.

FIG. 1f shows another aspect of the solar cell structure and method as provided for in the context of the described embodiments and/or methods of the present invention.

### DETAILED DESCRIPTION

According to the method, wafers free of saw damage are provided. If necessary, the front side of the wafers may have texturing produced in a manner known per se. In this case front side refers to the side subjected to solar radiation during later use of the solar cell.

The entire surface of the thus-treated wafer is then provided with a doping source. During deposition of the full-surface doping source and thereafter, weak initial diffusion of the dopant is performed until a first layer resistance area is obtained.

The doping source is subsequently structured, whereby as a result of the structuring only those areas remain which essentially correspond to the sections on the wafer to be subsequently contacted or which are larger than these contact sections by a predefined small amount.

This is followed by an additional second diffusion from the remaining areas of the doping source into the wafer volume until a second layer resistance area for the selective emitter is obtained. In this additional second diffusion step, a redistribution of the dopant introduced during the first diffusion is performed simultaneously with the goal of reducing the doping concentration in the areas near the surface which are no longer covered by the doping source provided that as a result of this treatment the layer resistance values in the first layer resistance area are greater than those of the second layer resistance area.

The doping source may have phosphosilicate glass (PSG).

The first layer resistance area is essentially 100 Ω/□ to 300 Ω/□ after conclusion of the two diffusions. The second layer resistance area for the emitter section below the subsequent contacts is between 30 Ω/□ and less than 100 Ω/□.

The doping source is structured in that an etching-resistant masking is applied on the areas to be retained with subsequent implementation of the etching step.

The masking may be implemented with the aid of screen printing, stencil printing, hot-melt screen printing, ink jet printing, dispensing, aerosol printing, hot-melt ink jet printing, or similar methods.

The etching mask is removed after the etching step.

The etching process may be performed using a wet chemical method, using plasma, or in a plasma-supported manner, the masking layer and any residue being stripped or incinerated by the creation of an oxygen plasma following the etching step.

As a supplementary method step, oxidation of the surface of the wafer is possible to achieve a further reduction of the surface concentration and to effect an injection of interstitial oxygen atoms into the wafer.

The exemplary embodiments and/or exemplary methods of the present invention are described in greater detail in the following on the basis of an exemplary embodiment and the drawing.

The figure shows a step sequence a) through f) in principle with the goal of forming a selective emitter by structuring the doping source until the front side is metalized, the processing of the back side being able to be performed by any method of the related art.

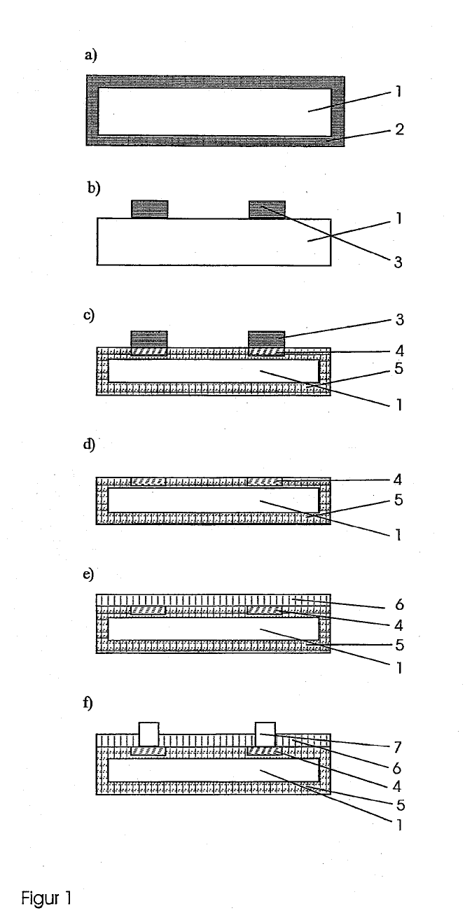

In the method for manufacturing a selective emitter having special properties due to additional driving in from the structured source according to the exemplary embodiment, a doping source, e.g., phosphosilicate glass (PSG), is applied on the saw-damage-etched and possibly textured wafer and is weakly diffused (FIG. 1a). The silicon wafer is designated by reference numeral 1 and the diffusion source applied over the entire surface is designated by reference numeral 2. The weakly diffused area is designated by reference numeral 5.

For example, a layer resistance between 100 Ω/□ and 200 Ω/□ is set in this step. This may take place in a combined process step including gas phase diffusion, e.g., phosphorus oxychloride (POCl₃), and temperature treatment, e.g., in a quartz tube furnace.

It is also possible to create the doping source, e.g., PSG, with the aid of atmospheric plasma chemical vapor deposition (APCVD) and to perform the initial weak diffusion step in a tube furnace or a continuous furnace with roller, chain belt, or lifting bar transport.

Diffusion source 2 applied over the entire surface is subsequently structured so that strip-shaped areas 3 remain as shown in FIG. 1b in a heavily simplified form.

The doping source is structured in such a way that the area to be subsequently electrically contacted is still covered by the source material but all other areas are no longer covered. For technological reasons, the source material may also be left protruding over or under this subsequent contact area.

The previously mentioned structuring of the doping or diffusion source is achievable using different methods.

For example, the areas in which the source layer is to be retained may be masked by an etching-resistant layer. Organic, dry-curing paints are considered, but not exclusively; wax-like organic materials, UV-hardening paints but also silicon-oxide-nitride layers produced by tempering of corresponding starting materials may be used as etching-resistant layers.

The masking areas or sections may be implemented with the aid of screen printing, stencil printing, hot-melt screen printing, ink jet printing, hot-melt ink jet printing, dispensing, aerosol printing, or similar methods.

The diffusion source is then removed in the unmasked areas by etching, an etching medium which etches the diffusion source with a high selectivity compared to the silicon base material of the wafer advantageously being selected here.

For example, wet-chemical etching in hydrofluoric acid (HF) may be used for PSG. Hydrofluoric acid etches PSG extremely quickly but barely etches silicon.

Alternatively, acids with the same property may be used in wet-chemical etching. However, a plasma step in the sense of dry etching may also be used. Fluorion-based etching processes, e.g., with CF₄, may also have the selectivity necessary for the PSG layer removal.

The masking layer is removed after this treatment. This may then take place using the same etching system as was used for the diffusion source removal. Organic layers may be removed using a wet-chemical method via suitable stripper solutions. Silicon-oxide-nitride layers may be etched using phosphoric acid.

If the source layer is etched using plasma, an oxygen plasma may then be used for incinerating organic substances or layers.

Additional options for structuring the diffusion source are the application of etching pastes in the areas in which the source layer is to be removed or dry etching using etching masks.

In a second diffusion step shown in FIG. 1c, strong doping 4 is formed in wafer 1 underneath local diffusion source 3. All other areas have weak doping 5b.

An emitter having a low layer resistance, which is very suitable for subsequent contacting, is therefore produced in the second diffusion process in the areas in which a diffusion source is still located.

Only the dopant already diffused into the silicon is redistributed in the areas in which no source layer is located as a dopant. This advantageously results in a reduction of doping concentration 5b in the area near the surface. This reduction is targeted and intentional and is thus very advantageous for the solar cell since an emitter with a lower emitter saturation current density may thus be produced.

The surface passivation may also be performed more effectively at a low doping concentration on the surface. The diffusion may be performed, for example, by temperature treatment in a quartz tube furnace or in a continuous furnace.

By setting the gas composition, e.g., by adding oxygen or steam, in the furnace, additional oxidation of the source layer and the source layer-free surface may take place. This allows a further reduction of the surface concentration. Moreover, the diffusion may be accelerated by oxidation.

FIG. 1d shows the situation after the removal of remaining diffusion sources 3.

FIG. 1e symbolically shows an applied anti-reflection layer 6.

The production of anti-reflection layer 6, the procedure of the edge isolation, and the production of metallization contacts 7 (see FIG. 1f) may be performed using different methods known per se. When applying front side contacts 7, it must be ensured that the provided contact areas (strong doping 4) are maintained.

As a result of the implementation of the method, it is possible to lower the recombination of free charge carriers in the emitter so that a higher current may be generated and therefore the efficiency of such solar cells is improved.

The emitter may also be passivated more effectively. As a result of this and due to the more favorable doping profile, the emitter saturation current is reduced, thus increasing the no-load voltage of the solar cell. Finally, the contact resistance of the front side metallization with respect to the emitter may be reduced.

The described method is characterized by particular simplicity and clear process control. Since only a small part of the wafer surface must be masked, less masking material is necessary. Numerous easily controllable materials may be used for masking typical diffusion sources. The etching of PSG as a doping source, for example, may be performed using hydrofluoric acid in a very cost-effective manner and is easily controlled. The indicated diffusion processes are relatively short and are performable at moderate temperatures. This saves energy and makes it possible to utilize the method for a broad spectrum of silicon starting materials and wafers produced therefrom. This also applies to wafers for which an excessively high temperature budget would reduce the service life.

1-10. (canceled)

11. A method for producing solar cells having a selective emitter, the method comprising:
providing a wafer free of saw damage;
applying a doping source over the entire surface of the wafer and weakly initially diffusing the dopant into the wafer until a first layer resistance area is obtained;
structuring the applied doping source, wherein only those areas which essentially correspond to the sections on the wafer which are to be subsequently contacted remain as a result of the structuring; and
conducting an additional second diffusion from the remaining areas of the doping source into the wafer volume until a second layer resistance area for the selective emitter is obtained and simultaneous redistribution of the dopant introduced during the first diffusion with the goal of reducing the doping concentration in the area near the surface which is no longer covered by the doping source, provided that the layer resistance values of the first layer resistance area are greater than those of the second layer resistance area.

12. The method of claim 11, wherein the doping source has phosphosilicate glass (PSG).

13. The method of claim 11, wherein the first layer resistance area after the second diffusion step is essentially between approximately 100 Ω/□ and 300 Ω/□.

14. The method of claim 11, wherein, for structuring the doping source, an etching-resistant masking is applied on the areas to be retained, and wherein at least one etching step is subsequently performed.

15. The method of claim 14, wherein the masking is implemented with the aid of one of screen printing, stencil printing, hot-melt screen printing, ink jet printing, dispensing, aerosol printing, hot-melt ink jet printing, and similar techniques.

16. The method of claim 14, wherein the etching mask is removed after the etching step is performed.

17. The method of claim 14, wherein the etching operation is performed in a plasma-supported manner, and wherein the masking layer and any organic deposits being incinerated by treatment with oxygen plasma after the etching.

18. The method of claim 11, wherein the surface of the wafer is oxidized to at least one of further reduce the surface concentration and accelerate the diffusion.

19. The method of claim 11, wherein the second layer resistance area is between 30 Ω/□ and <100 Ω/□.

20. A solar cell, comprising:
a solar cell arrangement, including a wafer free of saw damage having:
a first layer resistance area, which is obtained by applying a doping source over the entire surface of the wafer and weakly initially diffusing the dopant into the wafer, wherein the applied doping source is structured so that only those areas which essentially correspond to the sections on the wafer which are to be subsequently contacted remain as a result of the structuring; and
a second layer resistance area, for the selective emitter, which is obtained by conducting an additional second diffusion from the remaining areas of the doping source into the wafer volume, and simultaneous redistribution of the dopant introduced during the first diffusion with the goal of reducing the doping concentration in the area near the surface which is no longer covered by the doping source, provided that the layer resistance values of the first layer resistance area are greater than those of the second layer resistance area.
